(19) United States
(12) Patent Application Publication
(10) Pub. No.: US 2019/0252632 A1
(43) Pub. Date: Aug. 15, 2019

(54) PIXELATED SENSOR DEVICE WITH ORGANIC PHOTOACTIVE LAYER

(71) Applicant: FLEXENABLE LIMITED, Cambridge (GB)

(72) Inventor: Patrick TOO, Cambridge (GB)

(73) Assignee: FLEXENABLE LIMITED, Cambridge (GB)

(21) Appl. No.: 16/274,593

(22) Filed: Feb. 13, 2019

(30) Foreign Application Priority Data
Feb. 14, 2018 (GB) 1802379.6

(51) Int. Cl. H01L 51/44; H01L 27/30

(52) U.S. Cl. CPC H01L 51/442; H01L 27/307

(57) ABSTRACT

A pixelated optical sensor device, comprising: a stack of layers supported on a substrate and defining an array of pixel electrodes and circuitry for independently addressing each pixel electrode; an organic photoactive layer in electrical contact with the array of pixel electrodes; and one or more counter electrodes in electrical contact with the array of pixel electrodes via the organic photoactive layer; wherein the pixel electrodes are formed from a noble metal material, and the one or more counter electrodes comprise a poly(3,4-ethylenedioxythiophene) polystyrene sulfonate material.

Organic photoactive materials are of increasing interest for pixelated optical sensor devices, such as e.g. sensors for providing high resolution images of e.g. friction ridge patterns and/or vein patterns at human fingertips.

One existing pixelated sensor device comprises: a stack of layers defining an array of indium-tin-oxide (ITO) pixel electrodes and circuitry for independently addressing each pixel electrode; an organic photoactive material in electrical contact with the ITO pixel electrodes; and a counter electrode in electrical contact with the ITO pixel electrodes via the organic photoactive material.

ITO was considered to be the best material for the pixel electrodes for these sensor devices. The inventor for the present application was exploring whether the use of more opaque pixel electrodes might possibly improve the performance consistency/stability of the sensor device by providing extra light-shielding for the light-sensitive organic semiconductor channels of underlying circuitry, which are already covered by at least overlying opaque gate conductors in a top-gate architecture. Testing of the devices led to the surprising result that the use of a noble metallic material for the pixel electrodes provides increased responsivity.

There is hereby provided a pixelated optical sensor device, comprising: a stack of layers supported on a substrate and defining an array of pixel electrodes and circuitry for independently addressing each pixel electrode; an organic photoactive layer in electrical contact with the array of pixel electrodes; and one or more counter electrodes in electrical contact with the array of pixel electrodes via the organic photoactive layer; wherein the pixel electrodes are formed from a noble metal material, and the one or more counter electrodes comprise a poly(3,4-ethylenedioxythiophene) polystyrene sulfonate material.

According to one embodiment, the organic photoactive layer is in electrical contact with the pixel electrodes via one or more injection and/or charge transport layers; and/or the one or more counter electrodes are in electrical contact with the organic photoactive layer via one or more injection and/or charge transport layers.

According to one embodiment, said stack of layers comprises: a conductor layer defining an array of source conductors each providing the source electrodes for a respective row of pixel electrodes, and an array of drain conductors each providing the drain electrode for a respective pixel electrode; a semiconductor layer providing semiconductor channels between the source and drain electrodes for each pixel electrode; and another conductor layer defining an array of gate conductors each providing the gate electrode for a respective column of pixel electrodes.

According to one embodiment, the device further comprises: one or more driver chips having terminals connected to respective ones of the gate conductors, and terminals connected to respective ones of the source conductors.

There is also hereby provided a method of producing an optical sensor device, comprising: forming a stack of layers on a support substrate, the stack of layers defining an array of pixel electrodes and circuitry for independently addressing each pixel electrode; forming an organic photoactive layer in electrical contact with the array of pixel electrodes; and forming one or more counter electrodes in electrical contact with the array of pixel electrodes via the organic photoactive layer; wherein the pixel electrodes are formed from a noble metal material, and the one or more counter electrodes comprise a poly(3,4-ethylenedioxythiophene) polystyrene sulfonate material.

An embodiment of the invention is described in detail hereunder, by way of example only, with reference to the accompanying drawing, in which:

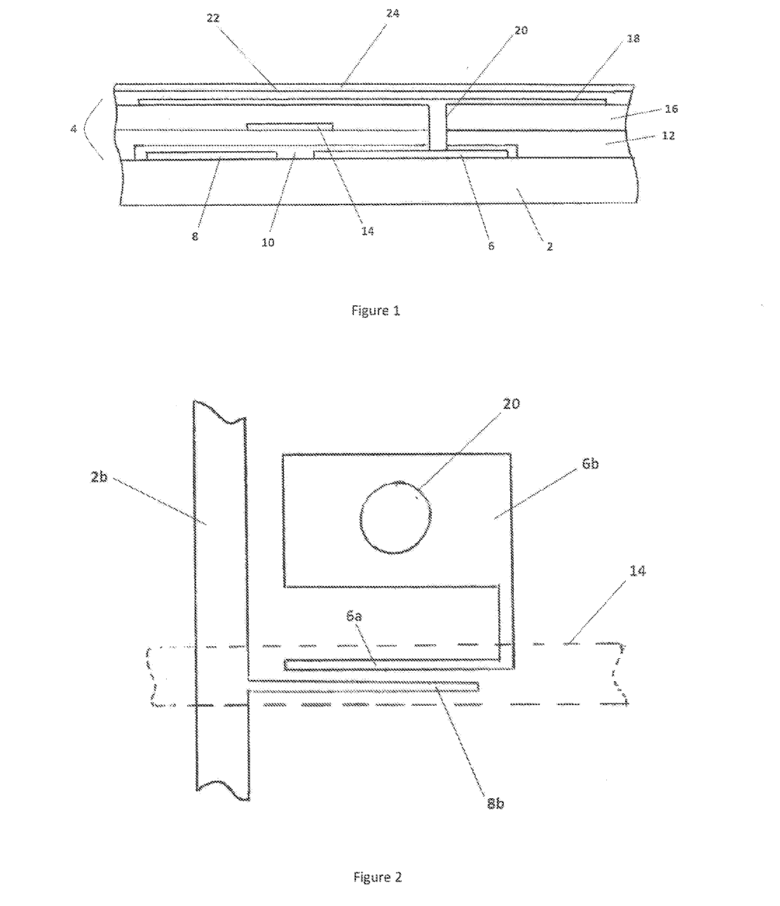

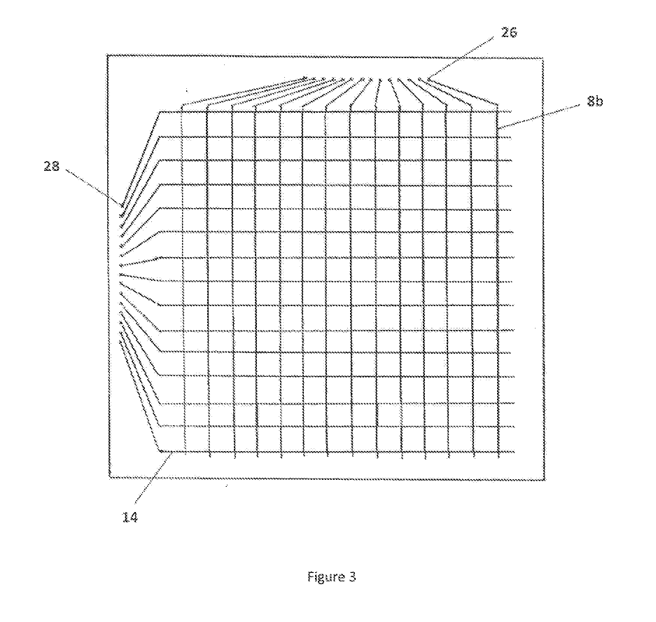

FIGS. 1 and 2 illustrate an example of a device architecture for a pixelated sensor device; and

FIG. 3 illustrates an example of an arrangement of source and gate conductors for a pixelated sensor device.

An embodiment of the invention is described for the example of an optical sensor device including an array of top-gate thin film transistors (TFTs), but the same technique is also applicable to sensor devices including an array of bottom-gate TFTs, or sensor devices including a combination of top-gate and bottom-gate TFTs.

In this example, the array of thin-film transistors is an array of organic thin film transistors (OTFTs). OTFTs comprise an organic semiconductor (such as e.g. an organic polymer or small-molecule semiconductor) for the semiconductor channels.

A stack 4 of conductor, semiconductor and insulating layers is formed on a support substrate 2 (such as e.g. a planarised plastic film). The stack includes a patterned, first conductor layer (which may itself comprise a stack of sub-layers) defining a set of source conductors 8 each providing a relative wide addressing line 8b extending to a respective terminal 26 at a peripheral edge region of the device and each providing relatively narrow finger-like source electrodes 8a for a respective set (e.g. row) of pixel electrodes 18. The patterned, first conductor layer also defines an array of drain conductors 6 each providing a relative narrow finger-like drain electrode 6a for a respective pixel electrode, and a drain pad 6b of relatively wide area to provide the base for an interlayer conductive connection to a respective pixel electrode 18.

The terms “row” and “column” here do not indicate any particular absolute directions, but together indicate a pair of substantially orthogonal directions. Also, the term source conductor is used here to refer to a conductor to which the pixel electrode is connected within the stack via a semiconductor channel, and the term “drain conductor” is used here to refer to a conductor via which the pixel electrode is connected within the stack to the semiconductor channel.

A semiconductor layer (such as a layer of a conjugated organic polymer) is formed over the first conductor layer to provide semiconductor channels 10 between the source and drain electrodes 8a, 6a for each pixel electrode 18. The semiconductor layer may be patterned so as to isolate each semiconductor channel 10 from any other semiconductor channel within the semiconductor layer. The first conductor layer may be modified before deposition of the semiconductor layer to improve the injection of charge carriers between the source/drain electrodes 8a, 6a and the semiconductor. This modification may, for example, comprise depositing an organic charge-injection material which forms a self-assembled monolayer of an organic material on the patterned first conductor layer.

A layer of gate dielectric material 12 (such as e.g. a layer of an insulating organic polymer) or a stack 12 of gate dielectric materials (e.g. a stack of two or more insulating organic polymers) is formed over the semiconductor layer.

A patterned second conductor layer is formed over the gate dielectric 12 to define an array of gate line conductors 14, each extending to a respective terminal 28 at an edge region and each providing the gate electrodes for a respective set (e.g. column) of pixel electrodes 18. Each pixel electrode 18 has its own unique combination of source and gate conductors, by which each pixel electrode 18 can be addressed independently of any other pixel electrode 18. In use, one or more driver chips are configured to apply “on” voltages to the gate conductors 14 in sequence via terminals 28 (such that the sets of TFTs associated with each respective gate conductor are turned on in sequence), and one or more driver chips measure an electrical parameter (indicative of the amount of light incident on the organic photoactive layer in the region of the pixel electrode) for each source conductor 8 via the respective terminal 26 as the gate conductors 14 are switched on sequentially. In this way, electrical measurements are made for each pixel electrode 18 in the array, which collection of measurements indicate the pattern of light incident on the organic photoactive layer 22.

A further insulating layer 16 (e.g. organic polymer layer) or stack of insulating layers 16 (e.g. stack of organic polymer layers) is formed over the second conductor layer, and a patterning process is performed to define in the insulating layers 12, 16 via holes 20 extending down to each drain conductor 6b.

A patterned layer of a noble metallic material (such as e.g. gold) is formed over the patterned insulator 16 to define an array of pixel electrodes 18 having a thickness greater than 200 nm, each pixel electrode 18 in direct electrical contact with a respective drain conductor 6 through a respective via hole 20. Other noble metal materials include: palladium, silver and platinum and metal alloys of one or more of these metal elements.

A continuous layer of an organic photoactive material 22 (e.g. photoactive organic polymer material) is formed over the array of pixel electrodes 18 for electrical contact with the pixel electrodes 18. In one example, the photoactive material 22 is one that is sensitive to light in the infra-red region of the electromagnetic spectrum, but the same technique is applicable to photoactive materials that are sensitive to light in other regions of the electromagnetic spectrum. For example, the photoactive material may comprise a bulk heterojunction material (BHJ) comprising an interpenetrating network of a first material having a band gap in the frequency region of interest, and a second material that forms a donor-acceptor (D-A) system with the first material. Light incident on the first material generates an exciton within the first material; upon diffusion to an interface between the first and second materials, the exciton separates into free charge carriers with the electron transferring to the one of the two materials with the largest electron affinity and the hole transferring to the material with the lower ionisation potential. For example, the first material may comprise an electron donor polymer such as poly(3-hexylthiophene) (P3HT) or poly[N-9′-heptadecanyl-2,7-carbazole-alt-5,5-(4′, 7′-di-2-thienyl-2′, 1′, 3′-benzothiadiazole)] (PCDTBT); and the second material may comprise an electron acceptor material such as an ester of a phenyl-substituted fullerene. Examples of such fullerene esters include PC60BM (phenyl-C60-butyric acid methyl ester) and PC70BM (phenyl-C70-butyric acid methyl ester).

The electrical contact between the photoactive material and the pixel electrodes may be via one or more charge injection and/or transport layers. In this example, a layer of zinc oxide (not shown) is interposed between the pixel electrodes 18 and the photoactive layer 22 as an electron injection layer, but other electron injection layers may also be used.

A transparent layer of counter electrode (cathode) material 24 (e.g. layer of poly(3,4-ethylenedioxythiophene) polystyrene sulfonate (PEDOT:PSS), which has been treated after deposition to increase its electrical conductivity) is then formed over the organic photoactive layer 22 for electrical contact to the organic photoactive layer. This electrical contact may also be via one or more charge injection and/or transport layers. In this example, a PEDOT:PSS aqueous dispersion available from Heraeus Deutschland GmbH & Co. KG under the product name Clevios™ HIL-E was used for the counter electrode material. This PEDOT:PSS material has a work function between 5.4 eV and 5.6 eV. The dispersion can produce films with very low film roughness of about 1 nm, has a neutral pH, and can be deposited by e.g. ink-jet printing, slot-die or bar coating by modifying the viscosity.

To test the device, the device was exposed to a source of light to which the photoactive material is sensitive (in this example, infra-red radiation (850 nm)) of a known irradiance value, and the detector response (current) was measured via the source conductor terminals 26.

A responsivity value (ratio of the detector response to the irradiance of the incident infra-red radiation) of 0.2 A/W was measured for the sensor device with gold pixel electrodes compared to a measured responsivity value of 0.14 A/W for substantially the identical sensor device but with ITO pixel electrodes instead of gold pixel electrodes.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A pixelated optical sensor device, comprising: a stack of layers supported on a substrate and defining an array of pixel electrodes and circuitry for independently addressing each pixel electrode; an organic photoactive layer in electrical contact with the array of pixel electrodes; and one or more counter electrodes in electrical contact with the array of pixel electrodes via the organic photoactive layer; wherein the pixel electrodes are formed from a noble metal material, and the one or more counter electrodes comprise a poly(3,4-ethylenedioxythiophene) polystyrene sulfonate material.

2. A device according to claim 1, wherein: the organic photoactive layer is in electrical contact with the pixel electrodes via one or more injection and/or charge transport layers; and/or the one or more counter electrodes are in electrical contact with the organic photoactive layer via one or more injection and/or charge transport layers.

3. A device according to claim 1, wherein said stack of layers comprises: a conductor layer defining an array of source conductors each providing the source electrodes for a respective row of pixel electrodes, and an array of drain conductors each providing the drain electrode for a respective pixel electrode; a semiconductor layer providing semiconductor channels between the source and drain electrodes for each pixel electrode; and another conductor layer defining an array of gate conductors each providing the gate electrode for a respective column of pixel electrodes.

4. A device according to claim 3, further comprising: one or more driver chips having terminals connected to respective ones of the gate conductors, and terminals connected to respective ones of the source conductors.

5. A method of producing an optical sensor device, comprising: forming a stack of layers on a support substrate, the stack of layers defining an array of pixel electrodes and circuitry for independently addressing each pixel electrode; forming an organic photoactive layer in electrical contact with the array of pixel electrodes; and forming one or more counter electrodes in electrical contact with the array of pixel electrodes via the organic photoactive layer; wherein the pixel electrodes are formed from a noble metal material, and the one or more counter electrodes comprise a poly(3,4-ethylenedioxythiophene) polystyrene sulfonate material.
